(19) United States
(12) Patent Application Publication
(10) Pub. No.: US 2026/0215099 A1
(43) Pub. Date: Jul. 23, 2026

(54) DISPLAY DEVICE

(71) Applicant: Magnolia White Corporation, Tokyo (JP)

(72) Inventors: Tomohiko NAGANUMA, Tokyo (JP); Junko NAGASAWA, Tokyo (JP)

(73) Assignee: Magnolia White Corporation, Tokyo (JP)

(21) Appl. No.: 19/444,247

(22) Filed: Jan. 9, 2026

(30) Foreign Application Priority Data
Jan. 20, 2025 (JP) 2025-007818

(51) Int. Cl. H10K 59/122; H10K 59/38; H10K 59/80

(52) U.S. Cl. CPC H10K 59/122; H10K 59/38; H10K 59/873

(57) ABSTRACT

According to one embodiment, a display device includes a substrate, a first lower electrode and a second lower electrode provided above the substrate and spaced apart from each other, a rib layer provided on the first lower electrode and the second lower electrode, a partition including a lower portion provided on the rib layer and having conductivity and an upper portion provided on the lower portion and protruding relative to side surfaces of the lower portion, a sealing layer provided directly above the partition and having a recessed portion, and a lens formed in a protruding shape and covering a part of a bottom surface of the recessed portion in a direction in which the first lower electrode and the second lower electrode are provided.

### CROSS-REFERENCE TO RELATED APPLICATIONS

This application is based upon and claims the benefit of priority from Japanese Patent Application No. 2025-007818, filed Jan. 20, 2025, the entire contents of which are incorporated herein by reference.

### FIELD

Embodiments described herein relate generally to a display device.

### BACKGROUND

Recently, display devices with organic light-emitting diodes (OLED) applied thereto as display elements have been put into practical use. This type of display devices demand a technique for improving display quality.

### BRIEF DESCRIPTION OF THE DRAWINGS

FIG. 1 is a view showing a configuration example of a display device according to the first embodiment.

FIG. 2 is a schematic plan view showing an example of the layout of subpixels.

FIG. 3 is a schematic plan view showing constituent elements overlapping the subpixels.

FIG. 4 is a schematic plan view showing other constituent elements overlapping the subpixels.

FIG. 5 is a schematic cross-sectional view of the display device along the V-V line of FIG. 3.

FIG. 6 is a view showing an example of a layer structure applicable to display elements.

FIG. 7 is a cross-sectional view showing a lens in an enlarged manner.

FIG. 8 is a cross-sectional view for describing effects of the display device according to the first embodiment.

FIG. 9A is a schematic cross-sectional view showing a manufacturing process of the display device according to the first embodiment.

FIG. 9B is a schematic cross-sectional view showing a process following the one shown in FIG. 9A.

FIG. 9C is a schematic cross-sectional view showing a process following the one shown in FIG. 9B.

FIG. 10 is a schematic plan view showing subpixels of a display device according to the second embodiment.

FIG. 11 is a schematic cross-sectional view of a display device according to the third embodiment.

FIG. 12 is a schematic plan view showing subpixels of a display device according to the fourth.

FIG. 13 is a schematic cross-sectional view of the display device along the XIII-XIII line of FIG. 12.

FIG. 14 is a view showing an example of a layer structure applicable to display elements of the display device according to the fourth embodiment.

FIG. 15 is a cross-sectional view showing a lens in an enlarged manner.

FIG. 16A is a schematic cross-sectional view showing a manufacturing process of the display device according to the fourth embodiment.

FIG. 16B is a schematic cross-sectional view showing a process following the one shown in FIG. 16A.

FIG. 16C is a schematic cross-sectional view showing a process following the one shown in FIG. 16B.

FIG. 16D is a schematic cross-sectional view showing a process following the one shown in FIG. 16C.

FIG. 17 is a schematic cross-sectional view of a display device according to the fifth embodiment.

### DETAILED DESCRIPTION

In general, according to one embodiment, a display device includes a substrate, a first lower electrode and a second lower electrode provided above the substrate and spaced apart from each other, a rib layer provided on the first lower electrode and the second lower electrode and having a first pixel aperture overlapping the first lower electrode and a second pixel aperture overlapping the second lower electrode, a partition including a lower portion provided on the rib layer and having conductivity and an upper portion provided on the lower portion and protruding relative to side surfaces of the lower portion, a first organic layer contacting the first lower electrode through the first pixel aperture, a second organic layer contacting the second lower electrode through the second pixel aperture, a first upper electrode provided on the first organic layer and contacting the lower portion, a second upper electrode provided on the second organic layer and contacting the lower portion, a sealing layer covering the first upper electrode and the second upper electrode and having a recessed portion located between the first lower electrode and the second lower electrode and provided directly above the partition, and a lens provided above the sealing layer, formed in a protruding shape, and covering a part of a bottom surface of the recessed portion in a direction in which the first lower electrode and the second lower electrode are provided.

According to another embodiment, a display device includes a substrate, a first lower electrode and a second lower electrode provided above the substrate and spaced apart from each other, a rib layer provided on the first lower electrode and the second lower electrode and having a first pixel aperture overlapping the first lower electrode and a second pixel aperture overlapping the second lower electrode, a partition including a lower portion provided on the rib layer and having conductivity and an upper portion provided on the lower portion and protruding relative to side surfaces of the lower portion, a first organic layer contacting the first lower electrode through the first pixel aperture, a second organic layer contacting the second lower electrode through the second pixel aperture, a first upper electrode provided on the first organic layer and contacting the lower portion, a second upper electrode provided on the second organic layer and contacting the lower portion, a sealing layer covering the first upper electrode and the second upper electrode and having a recessed portion located between the first lower electrode and the second lower electrode and provided directly above the partition, and a lens provided above the sealing layer, formed in a protruding shape, and entirely covering a bottom surface of the recessed portion in a direction in which the first lower electrode and the second lower electrode are provided.

Embodiments can provide a display device capable of improving display quality.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the figures, an X-axis, a Y-axis, and a Z-axis orthogonal to each other are described to facilitate understanding as needed. A direction parallel to the X-axis is referred to as an X-direction. A direction parallel to the Y-axis is referred to as a Y-direction. A direction parallel to the Z-axis is referred to as a Z-direction. When various elements are viewed parallel to the Z-direction, the appearance is defined as a plan view.

The display device of each embodiment is an organic electroluminescent display device comprising an organic light emitting diode (OLED) as a display element, and could be mounted on various types of electronic devices such as a television, a personal computer, a vehicle-mounted device, a tablet, a smartphone, a mobile phone, and a wearable terminal.

### First Embodiment

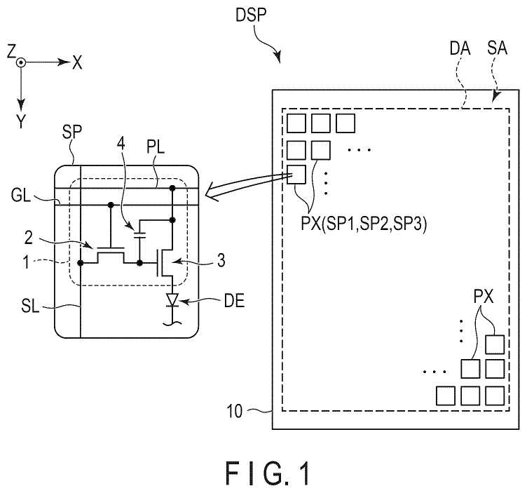

FIG. 1 is a view showing a configuration example of a display device DSP according to the first embodiment. The display device DSP comprises an insulating substrate 10. The substrate 10 has a display area DA for displaying images and a surrounding area SA outside the display area DA. The substrate 10 may be glass or a resinous film having flexibility.

In the present embodiment, the substrate 10 has a rectangular shape extending longer in the Y-direction in plan view. The shape of the substrate 10 in plan view is not limited to this shape and may be another shape such as a square shape, a circular shape, or an elliptic shape.

The display area DA comprises a plurality of pixels PX arranged in a matrix in the X-direction and the Y-direction. Each pixel PX includes a plurality of subpixels SP displaying different colors. The present embodiment assumes a case where each pixel PX includes a green subpixel SP1, a red subpixel SP2, and a blue subpixel SP3. Each pixel PX may include a subpixel SP that exhibits another color such as white in addition to the subpixels SP1, SP2, and SP3 or instead of one of the subpixels SP1, SP2, and SP3.

The subpixel SP comprises a pixel circuit 1 and a display element DE driven by the pixel circuit 1. The pixel circuit 1 comprises a pixel switch 2, a drive transistor 3, and a capacitor 4. The pixel switch 2 and the drive transistor 3 are, for example, switching elements constituted by thin-film transistors.

The display area DA has a plurality of scanning lines GL supplying the pixel circuit 1 of each subpixel SP with scanning signals, a plurality of signal lines SL supplying the pixel circuit 1 of each subpixel SP with video signals, and a plurality of power lines PL. In the example of FIG. 1, the scanning line GL and the power line PL extend in the X-direction, and the signal line SL extends in the Y-direction.

A gate electrode of the pixel switch 2 is connected to the scanning line GL. A source electrode of the pixel switch 2 is connected to the signal line SL. A drain electrode of the pixel switch 2 is connected to a gate electrode of the drive transistor 3 and the capacitor 4. A source electrode of the drive transistor 3 is connected to the power line PL and the capacitor 4. The drain electrode of the drive transistor 3 is connected to the display element DE.

The configuration of the pixel circuit 1 is not limited to the example of the figure. For example, the pixel circuit 1 may comprise more thin-film transistors and capacitors.

Though not described in detail, terminals for connecting IC chips and flexible printed circuit boards are provided in the surrounding area SA.

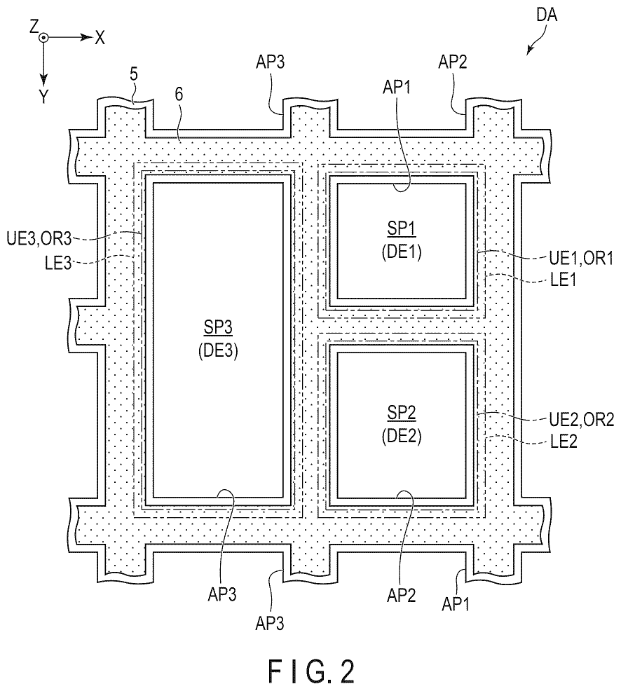

FIG. 2 is a schematic plan view showing an example of the layout of the subpixels SP1, SP2, and SP3. In the example of FIG. 2, the subpixels SP1 and SP2 are arranged with the subpixel SP3 in the X-direction. Further, the subpixels SP1 and SP2 are arranged in the Y-direction.

When the subpixels SP1, SP2, and SP3 are arranged in this layout, in the display area DA, a column in which the subpixels SP1 and SP2 are alternately arranged in the Y-direction and a column in which the plurality of subpixels SP3 are repeatedly arranged in the Y-direction are formed. These columns are alternately arranged in the X-direction. The layout of the subpixels SP1, SP2, and SP3 is not limited to the example of FIG. 2.

A rib layer 5 is provided in the display area DA. The rib layer 5 has pixel apertures AP1, AP2, and AP3 in the respective subpixels SP1, SP2, and SP3. In the example of FIG. 2, the pixel aperture AP2 is greater than the pixel aperture AP1, and the pixel aperture AP3 is greater than the pixel aperture AP2. Thus, among the subpixels SP1, SP2, and SP3, the aperture ratio of the subpixel SP3 is the greatest, and the aperture ratio of the subpixel SP1 is the least. The size and the shape of each of the pixel apertures AP1, AP2, and AP3 are not limited to the illustrated example.

The subpixel SP1 comprises a lower electrode LE1 (the first lower electrode), an upper electrode UE1 (the first upper electrode), and an organic layer OR1 (the first organic layer), which overlap the pixel aperture AP1 (the first pixel aperture). The subpixel SP2 comprises a lower electrode LE2 (the second lower electrode), an upper electrode UE2 (the second upper electrode), and an organic layer OR2 (the second organic layer), which overlap the pixel aperture AP2 (the second pixel aperture). The subpixel SP3 comprises a lower electrode LE3, an upper electrode UE3, and an organic layer OR3, which overlap the pixel aperture AP3.

Parts overlapping the pixel aperture AP1 of the lower electrode LE1, the upper electrode UE1, and the organic layer OR1 constitute a display element DE1 of the subpixel SP1. Parts overlapping the pixel aperture AP2 of the lower electrode LE2, the upper electrode UE2, and the organic layer OR2 constitute a display element DE2 of the subpixel SP2. Parts overlapping the pixel aperture AP3 of the lower electrode LE3, the upper electrode UE3, and the organic layer OR3 constitute a display element DE3 of the subpixel SP3. Each of the display elements DE1, DE2, and DE3 may further include a cap layer to be described later. The rib layer 5 surrounds each of the display elements DE1, DE2, and DE3. In the example of the present embodiment, the display elements DE1, DE2, and DE3 are configured to emit white light.

A conductive partition 6 is provided in the display area DA. The partition 6 is located above the rib layer 5 to entirely overlap the rib layer 5. In the example of FIG. 2, the partition 6 has a planar shape similar to that of the rib layer 5. That is, the partition 6 includes an aperture in each of the subpixels SP1, SP2, and SP3. From another viewpoint, each of the rib layer 5 and the partition 6 has a grating shape in plan view and surrounds each of the display elements DE1, DE2, and DE3. Further, the partition 6 surrounds the pixel apertures AP1, AP2, and AP3. The partition 6 functions as lines applying common voltage to the upper electrodes UE1, UE2, and UE3.

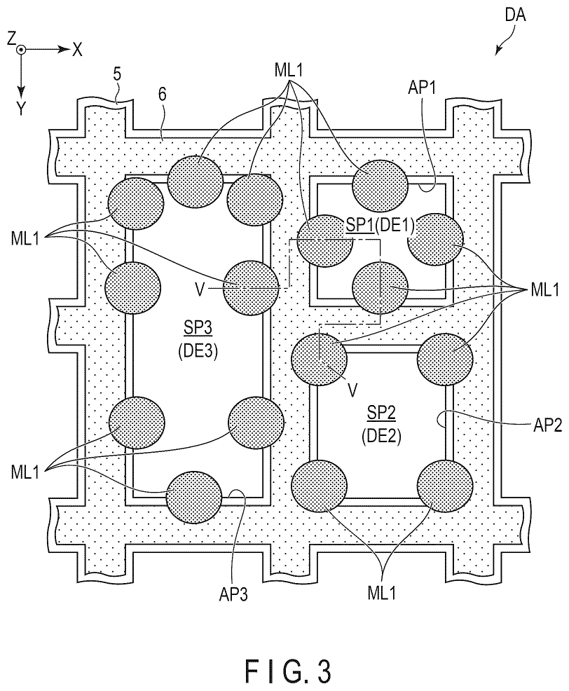

FIG. 3 is a schematic plan view showing constituent elements overlapping the subpixels SP1, SP2, and SP3. FIG. 3 omits the illustration of the lower electrode, the organic layer, the upper electrode, and the like that constitute the display element in each subpixel.

A plurality of lenses ML1 are provided in the display area DA. Each of the plurality of lenses ML1 has a circular shape in plan view. In the illustrated example, the plurality of lenses ML1 have the same diameter. Some of the lenses ML1 may have diameters different from those of the other lenses ML1. In one example, the diameter of the lens ML1 is equivalent to the respective intervals between the pixel apertures AP1, AP2, and AP3.

The plurality of lenses ML1 surround each of the apertures AP1, AP2, and AP3. The plurality of lenses ML1 are respectively provided directly above the pixel apertures AP1, AP2, and AP3. In the example shown in FIG. 3, four lenses ML1 are provided directly above the pixel aperture AP1. Four lenses ML1 are provided directly above the pixel aperture AP2. Eight lenses ML1 are provided above the pixel aperture AP3. The plurality of lenses ML1 are provided so as not to overlap each other.

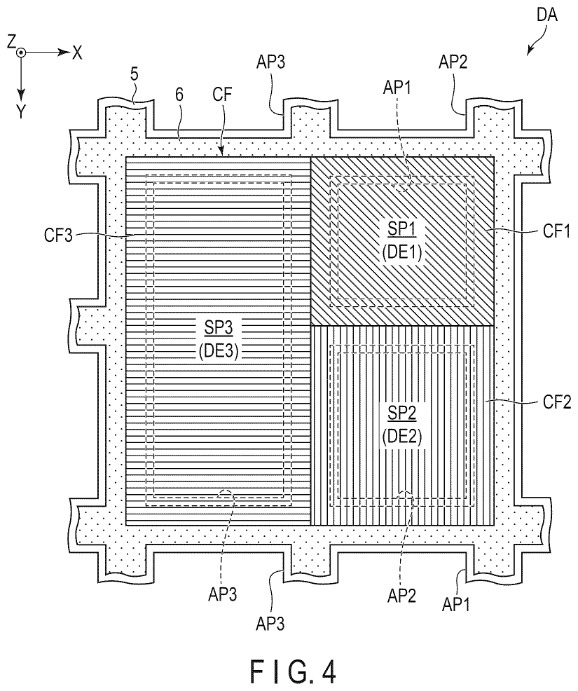

FIG. 4 is a schematic plan view showing other constituent elements overlapping the subpixels SP1, SP2, and SP3. Color filter layers CF are provided above the display elements DE1, DE2, and DE3.

The color filter layer CF includes a color filter CF1 colored in green (the first color filter), a color filter CF2 colored in red (the second color filter), and a color filter CF3 colored in blue. The color filter CF1 covers the pixel aperture AP1. A peripheral portion of the color filter CF1 overlaps the rib layer 5 and the partition 6 in plan view. The color filter CF2 covers the pixel aperture AP2. A peripheral portion of the color filter CF2 overlaps the rib layer 5 and the partition 6 in plan view. The color filter CF3 covers the pixel aperture AP3. A peripheral portion of the color filter CF3 overlaps the rib layer 5 and the partition 6 in plan view.

The color filter CF1 is configured not to transmit light of wavelengths other than light of the green wavelength. The color filter CF2 is configured not to transmit light of wavelengths other than light of the red wavelength. The color filter CF3 is configured not to transmit light of wavelengths other than light of the blue wavelength.

White light emitted from the display element DE1 passes through the color filter CF1, and thus the subpixel SP1 is displayed in green. Similarly, white light emitted from the display element DE2 passes through the color filter CF2, and thus the subpixel SP2 is displayed in red. Further, white light emitted from the display element DE3 passes through the color filter CF3, and thus the subpixel SP3 is displayed in blue.

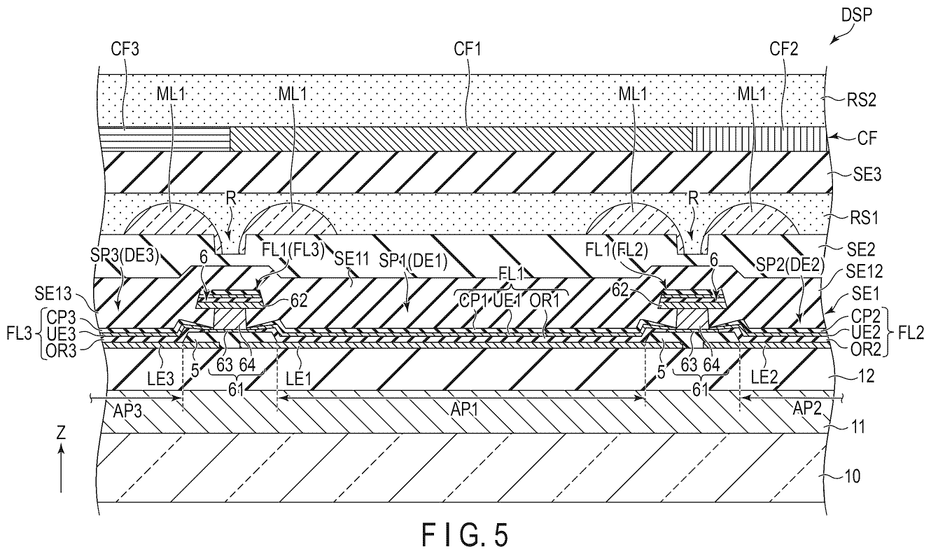

FIG. 5 is a schematic cross-sectional view of the display device DSP along the V-V line of FIG. 3. A circuit layer 11 is provided on the substrate 10 described above. The circuit layer 11 includes various circuits and lines such as the pixel circuit 1, the scanning line GL, the signal line SL, and the power lines PL shown in FIG. 1. The circuit layer 11 is covered with an organic insulating layer 12. The organic insulating layer 12 functions as a planarization film planarizing irregularities formed by the circuit layer 11.

The lower electrodes LE1, LE2, and LE3 are provided on the organic insulating layer 12 and are spaced apart from each other. The rib layer 5 is provided on the organic insulating layer 12 and the lower electrodes LE1, LE2, and LE3. End portions of the lower electrodes LE1, LE2, and LE3 are covered with the rib layer 5. Although not shown in the section in FIG. 5, the lower electrodes LE1, LE2, and LE3 are connected to the respective pixel circuits 1 (the drain electrode of the drive transistor 3 shown in FIG. 1) of the circuit layer 11 through respective contact holes provided in the organic insulating layer 12.

The partition 6 includes a conductive lower portion 61 provided on the rib layer 5 and an upper portion 62 provided on the lower portion 61. The upper portion 62 has the width greater than that of the lower portion 61. This configuration causes both end portions of the upper portion 62 to protrude relative to the side surfaces of the lower portion 61. This shape of the partition 6 is called an overhang shape.

In the example of FIG. 5, the lower portion 61 has a bottom layer 63 provided on the rib layer 5 and a stem layer 64 provided on the bottom layer 63. For example, the bottom layer 63 is formed to be thinner than the stem layer 64. In the example of FIG. 5, both end portions of the bottom layer 63 protrude relative to the side surfaces of the stem layer 64. Further, the both end portions of the bottom layer 63 are located between the end portion of the upper portion 62 and the side surface of the stem layer 64 in plan view. The upper portion 62 is provided on the stem layer 64.

The organic layer OR1 covers the lower electrode LE1 through the pixel aperture AP1. The upper electrode UE1 covers the organic layer OR1 and faces the lower electrode LE1. The organic layer OR2 covers the lower electrode LE2 through the pixel aperture AP2. The upper electrode UE2 covers the organic layer OR2 and faces the lower electrode LE2. The organic layer OR3 covers the lower electrode LE3 through the pixel aperture AP3. The upper electrode UE3 covers the organic layer OR3 and faces the lower electrode LE3. The upper electrodes UE1, UE2, and UE3 contact the side surface of the lower portion 61 of the partition 6.

The display element DE1 includes a cap layer CP1 covering the upper electrode UE1. The display element DE2 includes a cap layer CP2 covering the upper electrode UE2. The display element DE3 includes a cap layer CP3 covering the upper electrode UE3. The cap layers CP1, CP2, and CP3 function as optical adjustment layers which improve the extraction efficiency of the light emitted from the respective organic layers OR1, OR2, and OR3.

In the following explanation, a multilayer body including the organic layer OR1, the upper electrode UE1, and the cap layer CP1 is called a stacked film FL1. A multilayer body including the organic layer OR2, the upper electrode UE2, and the cap layer CP2 is called a stacked film FL2. A multilayer body including the organic layer OR3, the upper electrode UE3, and the cap layer CP3 is called a stacked film FL3.

In the present embodiment, the upper surface of the upper portion 62 is covered with the stacked films FL1, FL2, and FL3. The stacked films FL1, FL2, and FL3 and the partition 6 are covered with a sealing layer SE1 (the first sealing layer). The sealing layer SE1 has a first portion SE11, a second portion SE12, and a third portion SE13.

The first portion SE11 covering the stacked film FL1 is provided in the subpixel SP1. The second portion SE12 covering the stacked film FL2 is provided in the subpixel SP2. The third portion SE13 covering the stacked film FL3 is provided in the subpixel SP3. In the present embodiment, the first portion SE11, the second portion SE12, and the third portion SE13 are formed integrally.

The sealing layer SE1 is covered with a sealing layer SE2 (the second sealing layer). The sealing layer SE2 has a recessed portion R located directly above the partition 6. In the example of FIG. 5, the recessed portion R is located between the lower electrodes LE1 and LE2 and between the lower electrodes LE1 and LE3. The recessed portion R is formed along the partition 6 in plan view. That is, the recess portion R surrounds the pixel apertures AP1, AP2, and AP3 in plan view.

In the example of FIG. 5, the sealing layers SE1 and SE2 are stacked, but the sealing layers SE1 and SE2 may be integrally formed.

The plurality of lenses ML1 are provided on the sealing layer SE2. The lens ML1 has a shape protruding toward the side opposite to the substrate 10. The lens ML1 covers a part of the recessed portion R.

The plurality of lenses ML1 are covered with a resin layer RS1. The resin layer RS1 is covered with a sealing layer SE3 (the third sealing layer). The color filter layer CF is provided on the sealing layer SE3. The lenses ML1 are located between the sealing layer SE2 and the color filter CF. The color filter layers CF are covered with a resin layer RS2.

The color filter CF1 is provided above the display element DE1. The color filter CF2 is provided above the display element DE2. The color filter CF3 is provided above the display element DE3.

A cover member such as a polarizer, a protective film, and a cover glass may be further provided above the resin layer RS2. This cover member may be attached to the resin layer RS2 via, for example, an adhesive layer such as an optical clear adhesive (OCA).

The organic insulating layer 12 is formed of an organic insulating material such as a polyimide. Each of the rib layer 5 and the sealing layers SE1, SE2, and SE3 is formed of an inorganic insulating material such as a silicon nitride (SiNx), a silicon oxide (SiOx), or a silicon oxynitride (SiON). In one example, the rib layer 5 is formed of a silicon oxynitride, and each of the sealing layers SE1, SE2, and SE3 is formed of a silicon nitride. Each of the resin layers RS1 and RS2 is formed of, for example, a resinous material (organic insulating materials) such as an epoxy resin or an acrylic resin.

Each of the lower electrodes LE1, LE2, and LE3 has a reflective layer and a pair of conductive oxide layers covering the upper and lower surfaces of the reflective layer. The reflective layer is formed of, for example, a metal material having excellent light-reflecting properties, such as silver. Each of the conductive oxide layers can be formed of, for example, a transparent conductive oxide such as an indium tin oxide (ITO), an indium zinc oxide (IZO), or an indium gallium zinc oxide (IGZO).

The upper electrodes UE1, UE2, and UE3 are formed of, for example, a metal material such as an alloy of magnesium and silver (MgAg). For example, the lower electrodes LE1, LE2, and LE3 correspond to anodes, and the upper electrodes UE1, UE2, and UE3 correspond to cathodes.

Each of the cap layers CP1, CP2, and CP3 comprises, for example, a multilayer structure in which a plurality of transparent layers are stacked. These transparent layers may include a layer formed of an inorganic material and a layer formed of an organic material. The transparent layers have refractive indices different from each other. For example, the refractive indices of these transparent layers are different from the refractive indices of the upper electrodes UE1, UE2, and UE3 and the refractive index of the sealing layer SE1. At least one of the cap layers CP1, CP2, and CP3 may be omitted.

For example, each of the bottom layer 63 and the stem layer 64 of the partition 6 is formed of a metal material. For the metal material of the bottom layer 63, for example, molybdenum (Mo), titanium (Ti), a titanium nitride (TiN), a molybdenum-tungsten alloy (MoW), or a molybdenum-niobium alloy (MoNb) can be used. For the metal material of the stem layer 64, for example, aluminum (Al), an aluminum-neodymium alloy (AlNd), an aluminum-yttrium alloy (AlY), or an aluminum-silicon alloy (AlSi) can be used. For example, at least one of the bottom layer 63 and the stem layer 64 may comprise a stacked layer structure in which a plurality of layers are stacked. The stem layer 64 may include a layer formed of an insulating material.

For example, the upper portion 62 of the partition 6 includes a stacked layer structure comprising a lower layer formed of a metal material and an upper layer formed of a conductive oxide. For the metal material forming the lower layer, for example, titanium, a titanium nitride, molybdenum, tungsten, a molybdenum-tungsten alloy, or a molybdenum-niobium alloy may be used. For a conductive oxide forming the top layer, for example, an ITO or an IZO may be used. The upper portion 62 may comprise a single-layer structure of a metal material. The upper portion 62 may further include a layer formed of an insulating material.

Common voltage is applied to the partition 6. This common voltage is applied to each of the upper electrodes UE1, UE2, and UE3 contacting the side surfaces of the lower portions 61. Pixel voltages according to the video signals of the signal lines SL are applied to the lower electrodes LE1, LE2, and LE3 through the respective pixel circuits 1 provided in the subpixels SP1, SP2, and SP3.

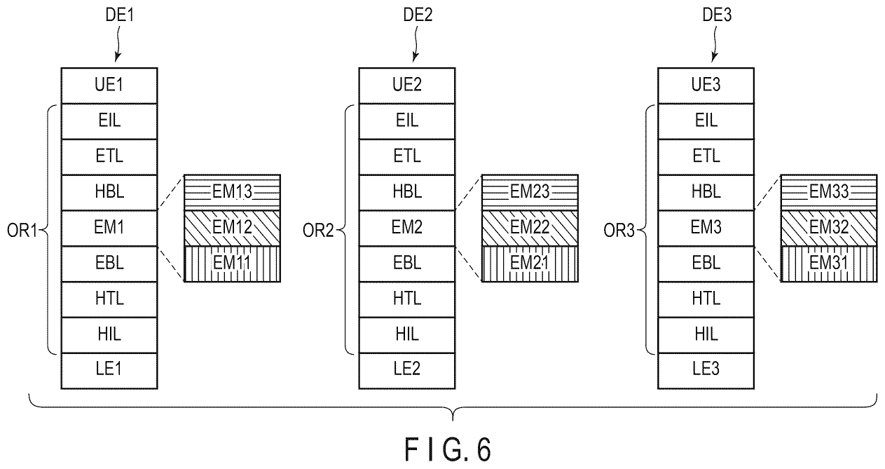

FIG. 6 is a view showing an example of a layer structure applicable to the display elements DE1, DE2, and DE3. Each of the organic layers OR1, OR2, and OR3 is formed of a plurality of thin films including a light emitting layer.

The organic layer OR1 comprises a hole injection layer HIL, a hole transport layer HTL, an electron blocking layer EBL, the light emitting layer EM1, a hole blocking layer HBL, an electron transport layer ETL, and an electron injection layer EIL. The hole injection layer HIL is located on the lower electrode LE1. The hole transport layer HTL is located on the hole injection layer HIL. The electron blocking layer EBL is located on the hole transport layer HTL. The light emitting layer EM1 is located on the electron blocking layer EBL. The hole blocking layer HBL is located on the light emitting layer EM1. The electron transport layer ETL is located on the hole blocking layer HBL. The electron injection layer EIL is located on the electron transport layer ETL. The upper electrode UE1 is located on the electron injection layer EIL.

The light emitting layer EM1 includes a light emitting layer EM11 emitting red light, a light emitting layer EM12 emitting green light, and a light emitting layer EM13 emitting blue light. The light emitting layer EM12 is located on the light emitting layer EM11. The light emitting layer EM13 is located on the light emitting layer EM12. The stacking order of the light emitting layers EM11, EM12, and EM13 is not limited to this example. The organic layer OR1 may include a light emitting layer emitting light of a color other than the above colors.

The organic layer OR2 comprises the hole injection layer HIL, the hole transport layer HTL, the electron blocking layer EBL, the light emitting layer EM2, the hole blocking layer HBL, the electron transport layer ETL, and the electron injection layer EIL. The hole injection layer HIL is located on the lower electrode LE2. The hole transport layer HTL is located on the hole injection layer HIL. The electron blocking layer EBL is located on the hole transport layer HTL. The light emitting layer EM2 is located on the electron blocking layer EBL. The hole blocking layer HBL is located on the light emitting layer EM2. The electron transport layer ETL is located on the hole blocking layer HBL. The electron injection layer EIL is located on the electron transport layer ETL. The upper electrode UE2 is located on the electron injection layer EIL.

The light emitting layer EM2 includes a light emitting layer EM21 emitting red light, a light emitting layer EM22 emitting green light, and a light emitting layer EM23 emitting blue light. The light emitting layer EM22 is located on the light emitting layer EM21. The light emitting layer EM23 is located on the light emitting layer EM22. The stacking order of the light emitting layers EM21, EM22, and EM23 is not limited to this example. The organic layer OR2 may include a light emitting layer emitting light of a color other than the above colors.

The organic layer OR3 comprises the hole injection layer HIL, the hole transport layer HTL, the electron blocking layer EBL, the light emitting layer EM3, the hole blocking layer HBL, the electron transport layer ETL, and the electron injection layer EIL. The hole injection layer HIL is located on the lower electrode LE3. The hole transport layer HTL is located on the hole injection layer HIL. The electron blocking layer EBL is located on the hole transport layer HTL. The light emitting layer EM3 is located on the electron blocking layer EBL. The hole blocking layer HBL is located on the light emitting layer EM3. The electron transport layer ETL is located on the hole blocking layer HBL. The electron injection layer EIL is located on the electron transport layer ETL. The upper electrode UE3 is located on the electron injection layer EIL.

The light emitting layer EM3 includes a light emitting layer EM31 emitting red light, a light emitting layer EM32 emitting green light, and a light emitting layer EM33 emitting blue light. The light emitting layer EM32 is located on the light emitting layer EM31. The light emitting layer EM33 is located on the light emitting layer EM32. The stacking order of the light emitting layers EM31, EM32, and EM33 is not limited to this example. The organic layer OR3 may include a light emitting layer emitting light of a color other than the above colors.

If necessary, the organic layers OR1, OR2, and OR3 may include other function layers such as a carrier generation layer in addition to the above function layers. Alternatively, the organic layers OR1, OR2, and OR3 may exclude at least one of the above function layers.

The organic layers OR1, OR2, and OR3 emit light in response to the application of a voltage. More specifically, when a potential difference is formed between the lower electrode LE1 and the upper electrode UE1, the light emitting layers EM11, EM12, and EM13 emit light. Red light emitted from the light emitting layer EM11, green light emitted from the light emitting layer EM12, and blue light emitted from the light emitting layer EM13 mix, whereby the display element DE1 displays white. The organic layers OR2 and OR3 emit light in the same manner as the organic layer OR1, and the display elements DE2 and DE3 display white.

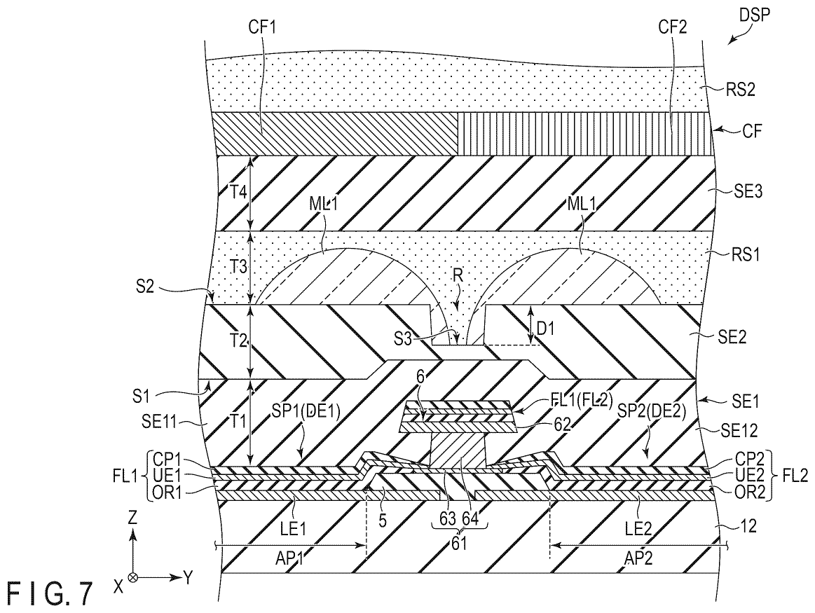

FIG. 7 is a cross-sectional view showing the lens ML1 in an enlarged manner. FIG. 7 shows the part between the subpixels SP1 and SP2 in an enlarged manner. FIG. 7 omits elements below the organic insulating layer 12.

The sealing layer SE2 has a lower surface S1 and an upper surface S2. The lower surface S1 faces the sealing layer SE1. In the example of FIG. 7, the lower surface S1 contacts the sealing layer SE1. The upper surface S2 is located on the opposite side of the lower surface S1. The upper surface S2 contacts the resin layer RS1 and the lens ML1.

The recessed portion R is formed in the upper surface S2. The recessed portion R has a bottom surface S3. The lens ML1 covers a part of the bottom surface S3 in the Y-direction (the direction in which the lower electrodes LE1 and LE2 are arranged). In the example of FIG. 7, two lenses ML1 cover a part of the bottom surface S3.

The two lenses ML1 are spaced apart from each other in the Y-direction. Thus, in the Y-direction, a part of the bottom surface S3 is not covered with the two lenses ML1. This part not covered by the lenses ML1 is covered with the resin layer RS1. That is, in this part, the sealing layer SE2 and the resin layer RS1 contact each other.

Here, a thickness of the sealing layer SE1 is defined as a thickness T1, a thickness of the sealing layer SE2 is defined as a thickness T2, a thickness of the resin layer RS1 is defined as a thickness T3, and a thickness of the sealing layer SE3 is defined as a thickness T4. The thicknesses T1, T2, T3, and T4 respectively correspond to the thicknesses of the parts overlapping the display elements DE1, DE2, and DE3 of the layers.

In the example of FIG. 7, the thicknesses T2, T3, and T4 are smaller than the thickness T1 (T1>T2, T3, T4). Further, the thicknesses T2, T3, and T4 are equivalent to each other (T2=T3=T4). The magnitude relationship between the thicknesses T1, T2, T3, and T4 is not limited to this example.

A depth of the recessed portion R is defined as a depth D1. The depth D1 corresponds to a distance in the Z-direction between the upper surface S2 and the bottom surface S3. In one example, the depth D1 is about half the thickness T2.

The refractive indices of the sealing layers SE1 and SE2 are equivalent to each other. The refractive index of the lens ML1 is smaller than the refractive index of the sealing layer SE2. The refractive index of the resin layer RS1 is smaller than the refractive index of the lens ML1. In one example, the refractive indices of the sealing layers SE1 and SE2 are 2.0, the refractive index of the lens ML1 is 1.6, and the refractive index of the resin layer RS1 is 1.4.

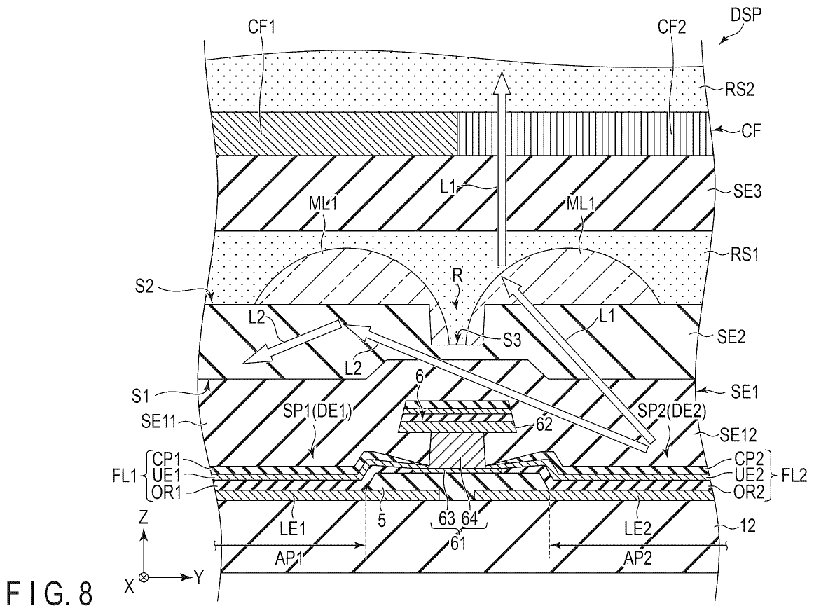

The following will describe the effects achieved by the display device DSP according to the present embodiment. FIG. 8 is a cross-sectional view for describing effects of the display device DSP according to the present embodiment.

Light rays emitted obliquely from the display element DE2 are defined as light rays L1 and L2. The light ray L2 is inclined relative to an axis parallel to the Z-direction to a greater extent than the light ray L1. The light rays L1 and L2 include light of the red wavelength emitted from the light emitting layer EM21, light of the green wavelength emitted from the light emitting layer EM22, and light of the blue wavelength emitted from the light emitting layer EM23.

The light ray L1 travels toward the lens ML1 overlapping the display element DE2 (the lens ML1 on the right side of FIG. 8). The light ray L1 that has reached the lens ML1 is refracted at an interface between the lens ML1 and the resin layer RS1. As described above, the refractive index of the resin layer RS1 is smaller than the refractive index of the lens ML1. Thus, the light ray L1 is refracted toward the Z-direction side (the front side of the display device DSP).

The refracted light ray L1 passes through the color filter CF2 located above the display element DE2. As described above, the color filter CF2 is configured not to transmit light of wavelengths other than light of the red wavelength. Thus, light in the green wavelength and light in the blue length in the light ray L1 are absorbed by the color filter CF2. That is, the light ray L1 that has passed through the color filter CF2 contains more light in the red wavelength light. As a result, the subpixel SP2 displays red.

On the other hand, the light ray L2 travels toward the lens ML1 overlapping the display element DE1 adjacent to the display element DE2 (the lens ML1 on the left side of FIG. 8). As described above, the refractive index of the lens ML1 is smaller than the refractive index of the sealing layer SE2. Thus, the light ray L2 is totally reflected at an interface between the lens ML1 and the sealing layer SE2. Thus, the light ray L2 can be prevented from entering the lens ML1 overlapping the display element DE1. As a result, the color mixing is suppressed, and a decrease in display quality of the display device DSP can be suppressed.

In addition, when the display device DSP comprises no lenses ML1, part of light rays emitted obliquely from the peripheral portion of the display element DE2 does not pass through the color filter CF2. This configuration having no lens ML1 may decrease luminance at the peripheral portion of the display element DE2 and render seams between the subpixels visible.

A potential countermeasure for this issue is providing lenses above the color filter layer CF to cover the respective pixel apertures AP1, AP2, and AP3. This countermeasure increases the sizes of the lenses relative to distances between the subpixels. Thus, adjacent lenses may be connected to each other, which may result in the lenses of the connected portion failing to exhibit effects.

In the present embodiment, the lens ML1 is located below the color filters CF. Further, the lenses ML1 are provided at the positions overlapping the peripheral portions of the pixel apertures AP1, AP2, and AP3, and do not cover the pixel apertures AP1, AP2, and AP3. Thus, the sizes of the lenses ML1 according to the present embodiment are smaller than those of the lenses in the example described above. In one example, the diameter of the lens ML1 is equivalent to the respective intervals between the pixel apertures AP1, AP2, and AP3.

Accordingly, light rays emitted obliquely from the peripheral portions of the display elements DE1, DE2, and DE3 are refracted by the lenses ML1 and travel in the Z-direction as described above. Thus, the present embodiment can suppress a decrease in luminance at the peripheral portions of the display elements DE1, DE2, and DE3.

Furthermore, adjacent lenses ML1 are less likely to be joined together. This configuration can enhance the effect of the lenses ML1. Thus, this configuration results in further decreasing luminance at the peripheral portions of the display elements DE1, DE2, and DE3.

Further, in the present embodiment, the sealing layer SE2 has the recessed portion R provided directly above the partition 6. Further, the lens ML1 covers a part of the bottom surface S3 of the recessed portion R. Thus, compared with a case where the sealing layer SE2 has no recessed portion R, the present embodiment has a greater amount of the light ray L1 refracted at the interface between the lens ML1 and the resin layer RS1. Thus, the present embodiment can suppress a decrease in luminance at the peripheral portions of the display elements DE1, DE2, and DE3. As a result, the present embodiment can suppress the color mixing and a decrease in display quality of the display device DSP.

Furthermore, in the present embodiment, providing the recessed portion R can increase the amount of the light ray L1 refracted by the lens ML1 without increasing a distance in the Z-direction between a top portion of the lens ML1 and the upper surface S2. Thus, the thickness T3 of the resin layer RS1 can be reduced. This configuration can reduce the amount of the light ray L1 that enters the color filter CF1 adjacent to the color filter CF2, among the light rays L1 refracted by the lens ML1. Thus, occurrence of the color mixing can be further suppressed. Further, a light-shielding layers do not have to be provided between the respective color filters CF1, CF2, and CF3 to suppress the color mixing. Thus, the present embodiment can improve luminance of each of the subpixels SP1, SP2, and SP3.

Furthermore, in the present embodiment, the sealing layer SE2 contacts the sealing layer SE1. That is, no other layer such as an organic insulating layer is interposed between the sealing layers SE1 and SE2. This configuration can reduce a distance in the Z-direction between the lens ML1 and the display elements DE1, DE2, and DE3. Thus, the amount of the light ray L1 incident on the lens ML1 can be increased. Further, this configuration further improves the luminance at the peripheral portions of the display elements DE1, DE2, and DE3. At the same time, the amount of the light ray L2 can be reduced. Furthermore, this configuration can reduce the amount of the light ray L2 that travels at an angle smaller than a critical angle. These effects result in suppressing occurrence of the color mixing.

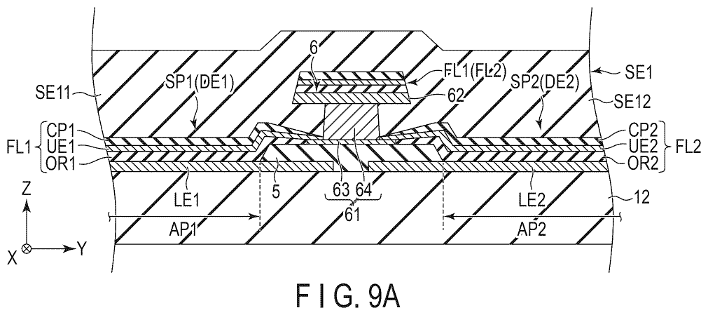

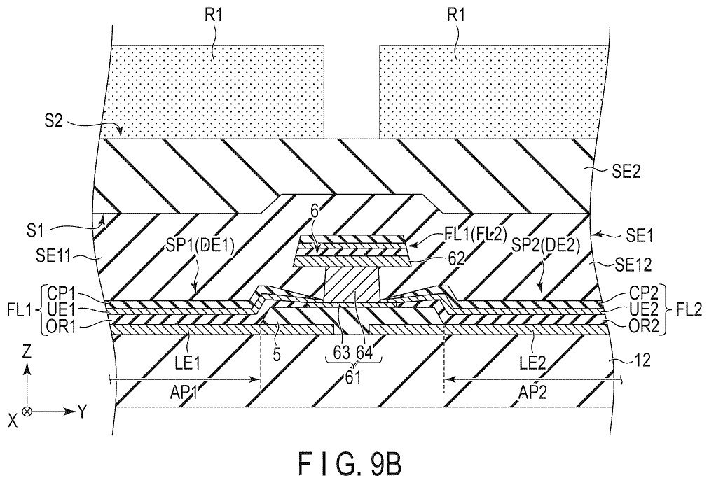

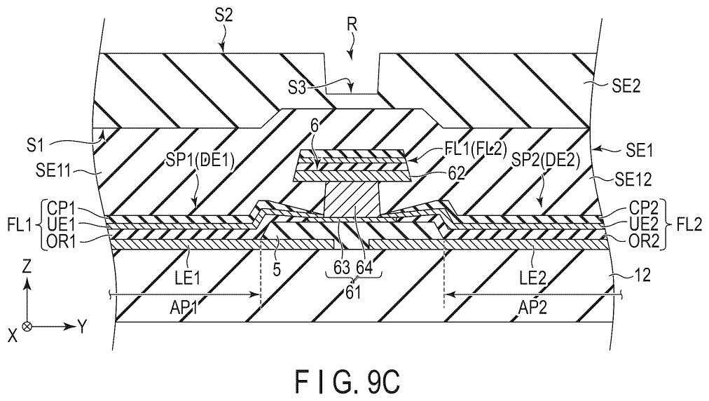

The following will describe an example of the forming method of the recessed portion R. FIG. 9A to FIG. 9C are schematic cross-sectional views showing manufacturing processes of the display device DSP according to the first embodiment. FIG. 9A to FIG. 9C omit the illustration of the elements below the organic insulating layer 12.

First, as shown in FIG. 9A, the lower electrodes LE1 and LE2, the rib layer 5, and the partition 6 are formed on the organic insulating layer 12. The rib layer 5 can be formed by chemical vapor deposition (CVD). The partition 6 is formed by forming respective layers corresponding to the bottom layer 63, the stem layer 64, and the upper portion 62 in the display area DA and then performing etching on the respective layers with a patterned resist used as a mask. The pixel apertures AP1 and AP2 are formed by performing etching on the rib layer 5 with a patterned resist used as a mask, after the formation of the partition 6. The step of forming the pixel apertures AP1 and AP2 may be performed before or after the step of forming the partition 6.

Next, the process for forming the display elements DE1 and DE2 is performed. The display elements DE1 and DE2 are formed in the same process. More specifically, materials of the organic layers OR1 and OR2 are formed over the entire surface of the display area DA. The formed layer is divided into a plurality of portions by the partition 6, thereby forming the organic layer OR1 covering the pixel aperture AP1 and the organic layer OR2 covering the pixel aperture AP2. The upper electrodes UE1 and UE2 and the cap layers CP1 and CP2 are also formed by the same steps. The sealing layer SE1 is not divided by the partition 6 and continuously covers the stacked films FL1 and FL2 and the partition 6. These processes form the display elements DE1 and DE2. Though not illustrated, the display element DE3 is also formed by the same process as the display elements DE1 and DE2.

The organic layers OR1 and OR2, the upper electrodes UE1 and UE2, and the cap layers CP1 and CP2 can be formed by, for example, vapor deposition. For example, the sealing layer SE1 may be formed by CVD.

Thereafter, as shown in FIG. 9B, the sealing layer SE2 covering the sealing layer SE1 is formed. The sealing layer SE2 is formed to cover the entire surface of the display area DA.

Thereafter, a resist R1 is provided on the sealing layer SE2. The resist R1 covers the pixel apertures AP1 and AP2. The resist R1 is not provided directly above the partition 6.

Thereafter, the dry etching process using the resist R1 as a mask is performed. As a result, as shown in FIG. 9C, a part removed from the resist R1 of the sealing layer SE2 is removed, and the recessed portion R is formed in the upper surface S2. After this etching process, the resist R1 is removed (stripped).

After the formation of the recessed portion R, the lenses ML1, the resin layer RS1, the sealing layer SE3, the color filter layers CF, and the resin layer RS2 are formed, and the display device DSP is completed.

The method of forming the recessed portion R is not limited to the example described above. In another example, after the formation of the sealing layer SE1, a groove corresponding to the recessed portion R is formed in the sealing layer SE1 by performing dry etching using a resist provided on the sealing layer SE1 as a mask. Thereafter, a material of the sealing layer SE2 is applied, and the material of the sealing layer SE2 flows into the groove. Thus, the recessed portion R having a shape corresponding to the groove is formed in the upper surface S2.

### Second Embodiment

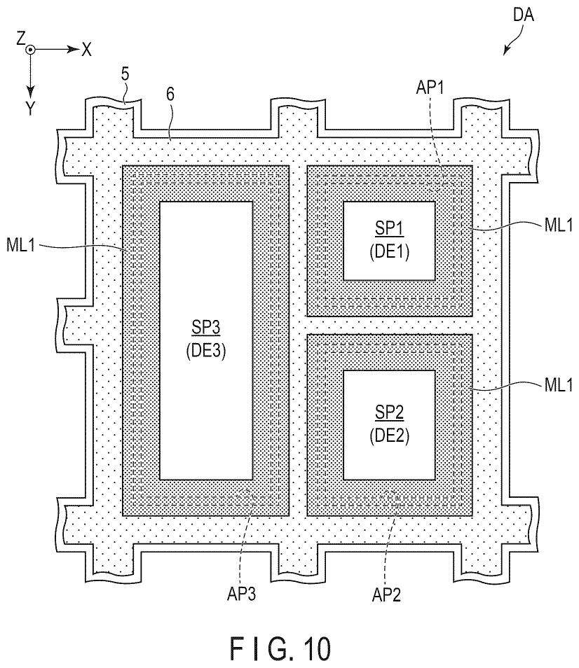

FIG. 10 is a schematic plan view showing the subpixels SP1, SP2, and SP3 of the display device DSP according to the second embodiment. The same configuration elements as those of the first embodiment are denoted by the same reference numbers, and their overlapping descriptions are omitted as appropriate.

In the second embodiment, the shape of the lens ML1 differs from that in the first embodiment. In the example of FIG. 10, the lens ML1 surrounds each of the pixel apertures AP1, AP2, and AP3. That is, one lens ML1 surrounds the pixel aperture AP1, one lens ML1 surrounds the pixel aperture AP2, and one lens ML1 surrounds the pixel aperture AP3. The lens ML1 is provided along the peripheral portion of each of the pixel apertures AP1, AP2, and AP3. This configuration can achieve the same effects as those described above.

### Third Embodiment

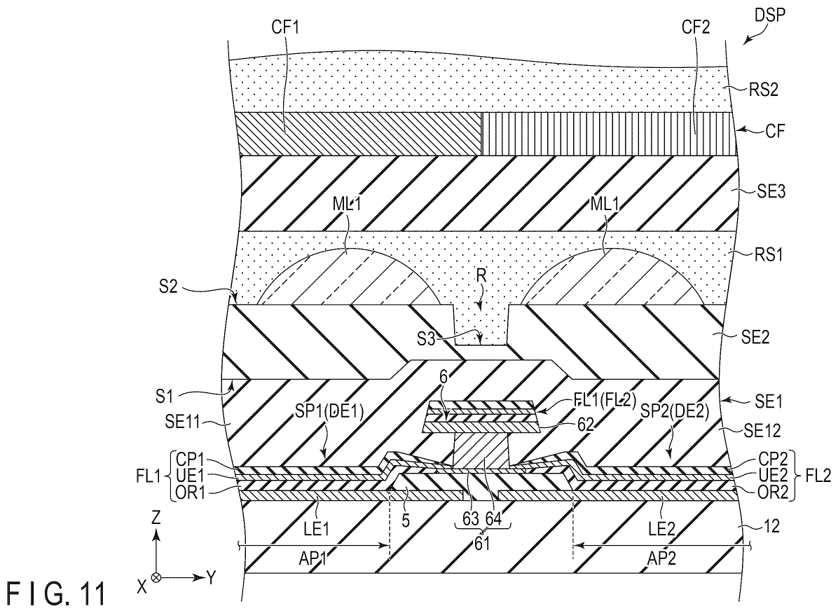

FIG. 11 is a schematic cross-sectional view of the display device DSP according to the third embodiment. In the example of FIG. 11, the bottom surface S3 of the recessed portion R is not covered with the lens ML1. Of the sealing layer SE2, the lens ML1 contacts the upper surface S2 alone. Thus, the recessed portion R is covered with the resin layer RS1.

The refractive index of the resin layer RS1 is smaller than the refractive index of the sealing layer SE2. Thus, light rays emitted obliquely from the display elements DE1, DE2, and DE3 are totally reflected at the recessed portion R. Thus, light rays are prevented from entering adjacent subpixels SP1, SP2, and SP3.

### Fourth Embodiment

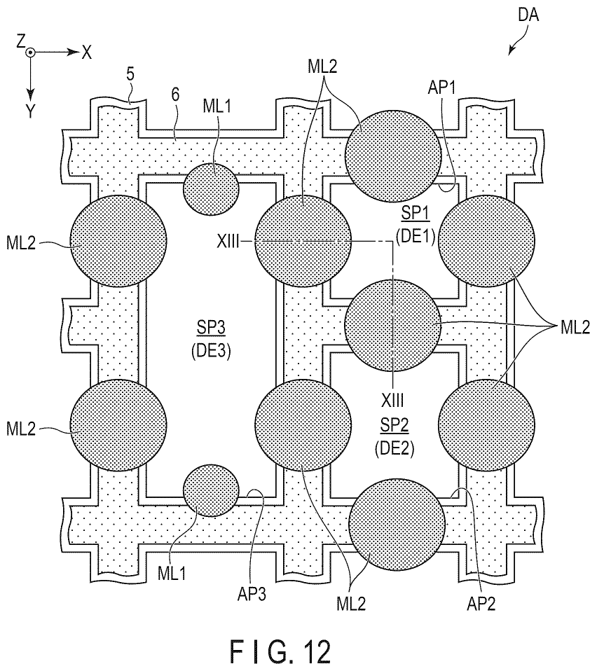

FIG. 12 is a schematic plan view showing the subpixels SP1, SP2, and SP3 of the display device DSP according to the fourth embodiment.

The display device DSP according to the fourth embodiment includes the lens ML1 overlapping any one of the pixel apertures AP1, AP2, and AP3 and the lens ML2 overlapping a plurality of the pixel apertures among the pixel apertures AP1, AP2, and AP3. In the example of FIG. 12, the lens ML1 overlapping the pixel aperture AP3, the lens ML2 overlapping the pixel apertures AP1 and AP2, the lens ML2 overlapping the pixel apertures AP2 and AP3, and the lens ML2 overlapping the pixel apertures AP1 and AP3 are provided in the display area DA. The diameter of the lens ML2 is larger than the diameter of the lens ML1. In one example, the diameter of the lens ML2 is at least twice the diameter of the lens ML1.

In the example of FIG. 12, the lens ML1 is provided between pixel apertures AP3 adjacent to each other in the Y-direction. The lens ML1 may be provided between the pixel apertures AP1 and AP2, between the pixel apertures AP2 and AP3, or between the pixel apertures AP1 and AP3. The lens ML2 may be provided between the pixel apertures AP3 adjacent to each other in the Y-direction.

The number and layout of the lenses ML1 and ML2 are not limited to the example of FIG. 12. Not the lens ML1 but the lens ML2 may be provided in the display area DA. Alternatively, not the lens ML2 but the lens ML1 may be provided in the display area DA.

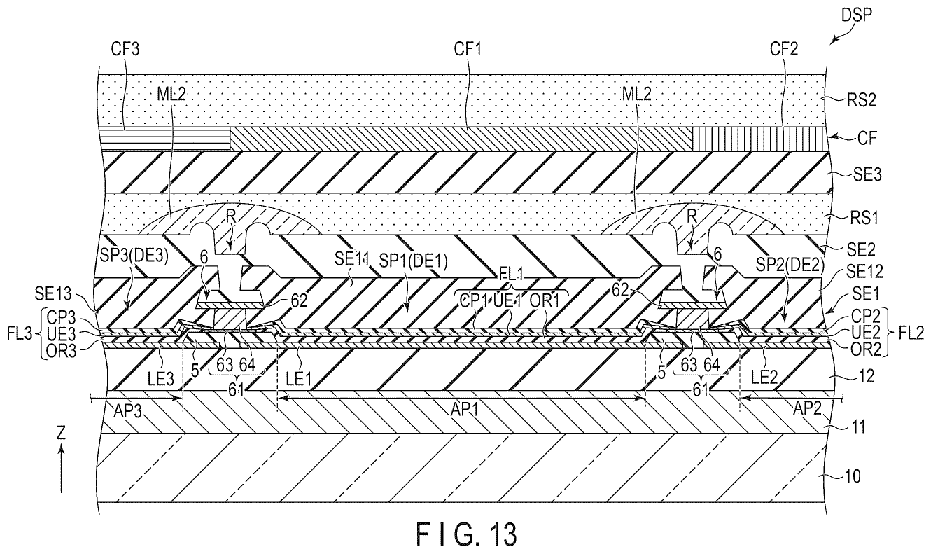

FIG. 13 is a schematic cross-sectional view of the display device DSP along the XIII-XIII line of FIG. 12. In the example of FIG. 13, the first portion SE11, the second portion SE12, and the third portion SE13 are spaced apart from each other. More specifically, the first portion SE11 on the partition 6 between the subpixels SP1 and SP2 is spaced apart from the second portion SE12 on the partition 6. Further, the first portion SE11 on the partition 6 between the subpixels SP1 and SP3 is spaced apart from the third portion SE13 on the partition 6.

For example, gaps are formed between the respective first portion SE11, second portion SE12 and third portion SE13 and the upper portion 62 of the partition 6. The stacked films FL1, FL2, and FL3 may be provided in at least part of these gaps.

The sealing layer SE2 continuously covers the first portion SE11, the second portion SE12, and the third portion SE13. The sealing layer SE2 contacts the upper surface of the upper portion 62 between the first portion SE11 and the second portion SE12. Further, the sealing layer SE2 contacts the upper surface of the upper portion 62 between the first portion SE11 and the third portion SE13.

The lenses ML2 are provided between the display elements DE1 and DE2 and between the display elements DE1 and DE3. The lens ML2 provided between the display elements DE1 and DE2 completely covers the recessed portion R in the arrangement direction of the display elements DE1 and DE2. The lens ML2 provided between the display elements DE1 and DE3 completely covers the recessed portion R in the arrangement direction of the display elements DE1 and DE3.

The organic layers OR1, OR2, and OR3 are configured to emit light in mutually different colors. The organic layer OR1 is configured to emit green light. The organic layer OR2 is configured to emit red light. The organic layer OR3 is configured to emit blue light.

The color filter CF1 is provided above the organic layer OR1 and is colored in the same color as the color emitted from the organic layer OR1 (green). The color filter CF2 is provided above the organic layer OR2 and is colored in the same color as the color emitted from the organic layer OR2 (red). The color filter CF3 is provided above the organic layer OR3 and is colored in the same color as the color emitted from the organic layer OR3 (blue).

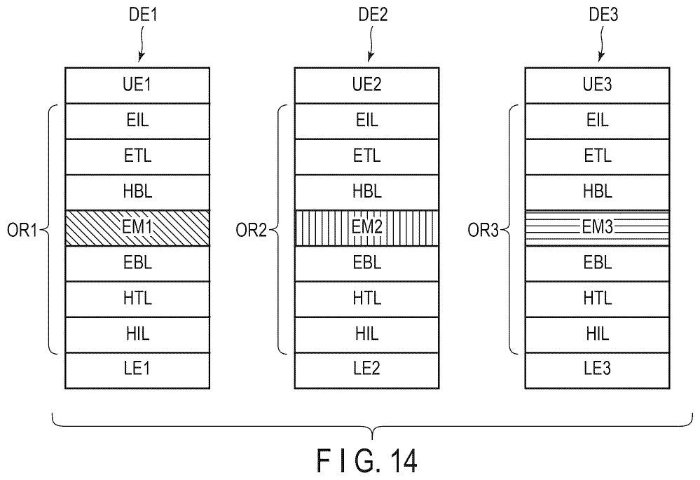

FIG. 14 is a view showing an example of a layer structure applicable to the display elements DE1, DE2, and DE3 of the display device DSP according to the fourth embodiment.

The light emitting layer EM1 is formed of a material emitting light in a green wavelength range. The light emitting layer EM2 is formed of a material emitting light in a red wavelength range. The light emitting layer EM3 is formed of a material emitting light in a blue wavelength range. The organic layers OR1, OR2, and, OR3 each may have other structures such as a tandem structure including a plurality of light emitting layers.

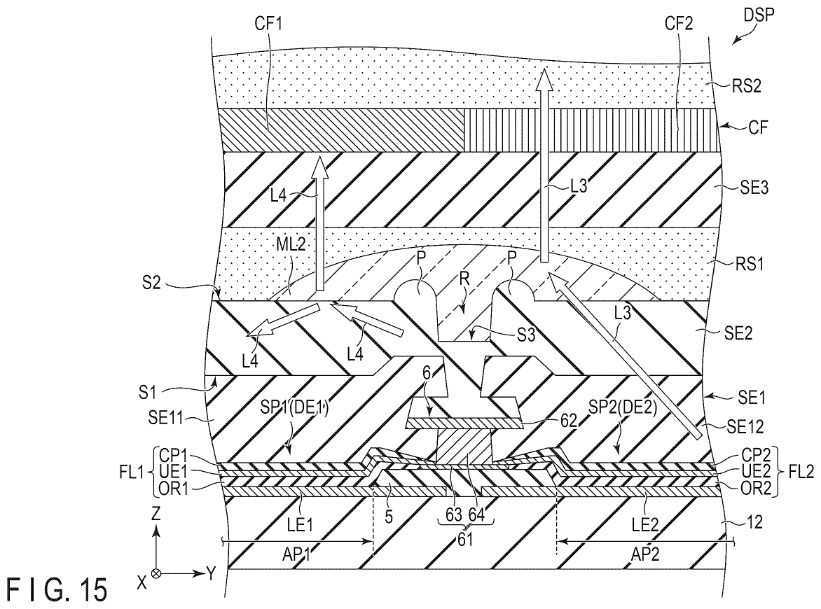

FIG. 15 is a cross-sectional view showing the lens ML2 in an enlarged manner. The lens ML2 completely covers the bottom surface S3 in the Y-direction (the direction in which the lower electrodes LE1 and LE2 are arranged). The refractive index of the lens ML2 is equivalent to the refractive index of the lens ML1.

The sealing layer SE2 has a protrusion portion P formed on the upper surface S2. The convex portion P is located above the partition 6 and is formed along the partition 6. The protrusion portion P is adjacent to both sides of the recessed portion R. In the example of FIG. 15, the cross-sectional shape of the protrusion portion P is semicircular. The shape is not limited to the example. The lens ML2 covers the protrusion portion P.

The following will describe the effects achieved by the display device DSP according to the fourth embodiment. As shown in FIG. 15, light rays emitted obliquely from the display element DE2 are defined as light rays L3 and L4. The light ray L4 is inclined relative to an axis parallel to the Z-direction to a greater extent than the light ray L3. The light rays L3 and L4 contain a large amount of light of a red wavelength emitted from the light emitting layer EM2.

Similarly to the light ray L1 shown in FIG. 8, the light ray L3 is refracted toward the Z-direction side (the front side of the display device DSP) at the interface between the lens ML1 and the resin layer RS1. The refracted light ray L3 passes through the color filter CF2 located above the display element DE2. As described above, the color filter CF2 is configured not to transmit light of wavelengths other than light of the red wavelength. Accordingly, the light ray L3, which contains a large amount of light of the red wavelength, passes through the color filter CF2 without being mostly absorbed by the color filter CF2.

On the other hand, the light ray L4 travels toward the subpixel SP1 side. A part of the light ray L4 is totally reflected at the interface between the lens ML2 and the sealing layer SE2, similarly to the light ray L2 shown in FIG. 8. However, depending on the emission angle of the light ray L4, the light ray L4 may travel straight across the interface between the lens ML2 and the sealing layer SE2 and may be refracted toward the Z-direction side at the interface between the lens ML2 and the resin layer RS1.

In such a case, the light ray L4 travels toward the color filter CF1 located above the display element DE1. As described above, the color filter CF1 is configured not to transmit light of wavelengths other than light of the green wavelength. Accordingly, the light ray L4, which contains a large amount of light of the red wavelength, passes through the color filter CF1. Thus, this configuration can suppress the color mixing and a decrease in the display quality of the display device DSP. This configuration can achieve the same effects as those described above.

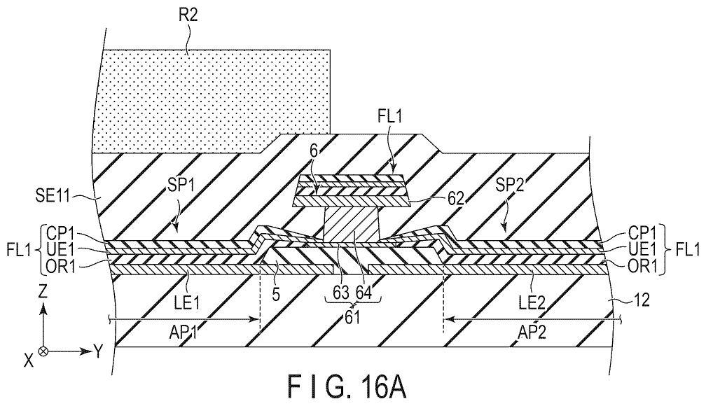

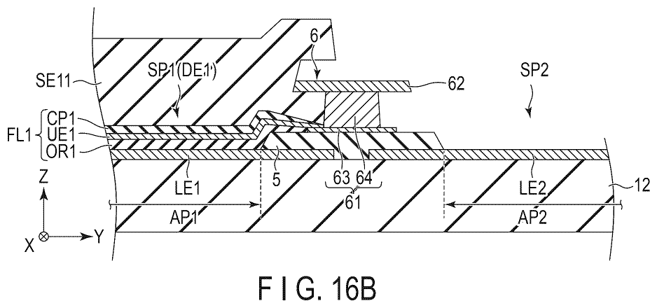

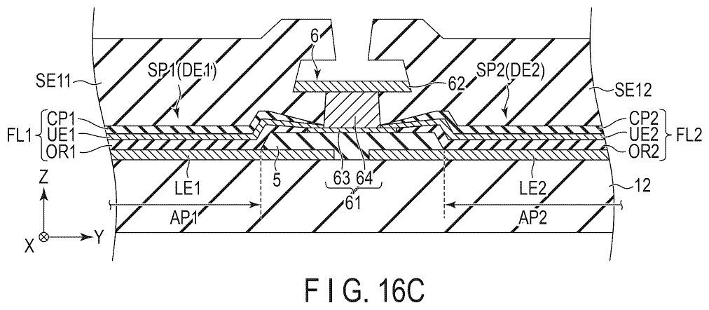

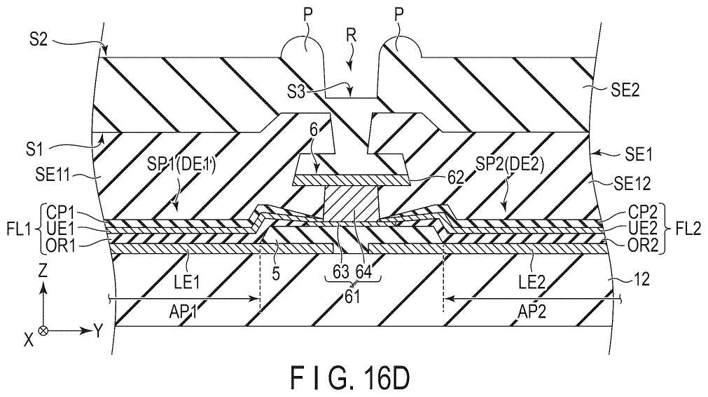

The following will describe an example of the forming method of the recessed portion R of the present embodiment. FIG. 16A to FIG. 16D are schematic cross-sectional views showing manufacturing processes of the display device DSP according to the fourth embodiment. FIG. 16A to FIG. 16D omit the illustration of the elements below the organic insulating layer 12.

The methods of forming the organic insulating layer 12, the lower electrodes LE1 and LE2, the rib layer 5, the partition 6, and the pixel apertures AP1 and AP2 are the same as those in the first embodiment. As shown in FIG. 16A, after the formation of the pixel apertures AP1 and AP2, the stacked film FL1 and the first portion SE11 are formed to cover the entire surface of the display area DA. The partition 6 divides the stacked film FL1 into a plurality of parts. The first portion SE11 continuously covers these parts, into which the stacked film FL1 has been divided, and the partition 6.

Subsequently, the stacked film FL1 and the first portion SE11 are patterned. In this patterning, a resist R2 is provided on the first portion SE11 as shown in FIG. 16A. The resist R2 covers the pixel aperture AP1 and a part of the partition 6 around the pixel aperture AP1.

Thereafter, the etching process using the resist R2 as a mask is performed. This process removes parts exposed from the resist R2 of the stacked film FL1 and the first portion SE11 as shown in FIG. 16B. In other words, the parts that overlap the lower electrode LE1 of the stacked film FL1 and the sealing layer SE11 remain, and the other parts are removed. This process forms the display element DE1 in the subpixel SP1. This etching process may include wet etching and dry etching performed in order for the first portion SE11, the cap layer CP1, the upper electrode UE1, and the organic layer OR1. After these etching processes, the resist R2 is removed (stripped).

The stacked film FL1 located under the first portion SE11 on the partition 6 is also removed in wet etching for the stacked film FL1. This process forms a gap between the first portion SE11 located above the partition 6 and the partition 6. The stacked film FL1 constituting the display element DE1 is completely surrounded by the first portion SE11 and the partition 6. Thus, this stacked film FL1 is not corroded by the wet etching.

Next, the process for forming the display element DE2 is performed as shown in FIG. 16C. The display element DE2 can be formed by the same procedure as that of the display element DE1. Next, the process for forming the display element DE3 is performed. The display element DE3 can be formed by the same procedures as those of the display elements DE1 and DE2.

Here, the above description assumes that the display elements DE1, DE2, and DE3 are formed in this order. However, the display elements DE1, DE2, and DE3 may be formed in another order.

After the formations of the display elements DE1, DE2, and DE3, the sealing layer SE2 is formed as shown in FIG. 16D. Unlike in the first embodiment, the recessed portion R is formed without etching in the fourth embodiment. More specifically, the material of the sealing layer SE2 flows into the gap between the first portion SE11 and the second portion SE12 above the partition 6, forming the recessed portion R. In the first portion SE11 and the second portion SE12, parts located above the partition 6 are raised relative to the parts covering the pixel apertures AP1 and AP2. Thus, the shape of these raised parts are transferred to the sealing layer SE2. Thus, the protrusion portion P is formed.

After the formation of the sealing layer SE2, the lenses ML1 and ML2, the resin layer RS1, the sealing layer SE3, the color filter layers CF, and the resin layer RS2 are formed, and the display device DSP is completed. The method of forming the recessed portion R is not limited to the example described above.

### Fifth Embodiment

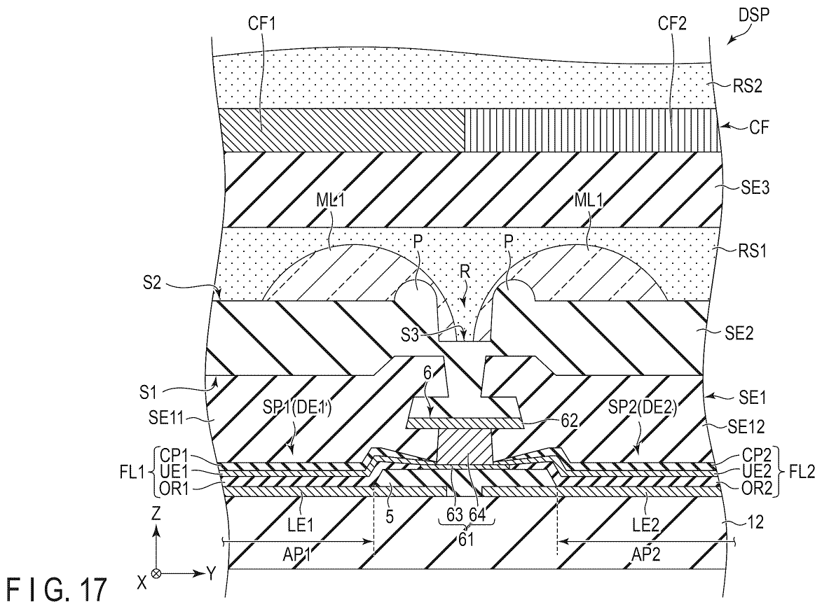

FIG. 17 is a schematic cross-sectional view of the display device DSP according to the fifth embodiment. The display device DSP according to the fifth embodiment does not comprise the lens ML2. Thus, the arrangement of the lens ML1 is the same as the one in the example shown in FIG. 3. The configurations of the display elements DE1, DE2, and DE3 are the same as those shown in FIG. 14.

The lens ML1 covers a part of the bottom surface S3. The lens ML1 covers the protrusion portion P adjacent to the recessed portion R. This configuration can achieve the same effects as those described above.

All of the display devices that can be implemented by a person of ordinary skill in the art through arbitrary design changes to the display device described above as the embodiment of the present invention come within the scope of the present invention as long as they are in keeping with the spirit of the present invention.

Various modification examples which may be conceived by a person of ordinary skill in the art in the scope of the idea of the present invention will also fall within the scope of the invention. For example, additions, deletions or changes in design of the constituent elements or additions, omissions, or changes in condition of the processes arbitrarily conducted by a person of ordinary skill in the art, in the above embodiments, fall within the scope of the present invention as long as they are in keeping with the spirit of the present invention.

In addition, the other advantages of the aspects described in the embodiments, which are obvious from the descriptions of the present specification or which can be arbitrarily conceived by a person of ordinary skill in the art, are considered to be achievable by the present invention as a matter of course.

What is claimed is

1. A display device, comprising:
a substrate;
a first lower electrode and a second lower electrode provided above the substrate and spaced apart from each other;
a rib layer provided on the first lower electrode and the second lower electrode and having a first pixel aperture overlapping the first lower electrode and a second pixel aperture overlapping the second lower electrode;
a partition comprising a lower portion provided on the rib layer and having conductivity and an upper portion provided on the lower portion and protruding relative to side surfaces of the lower portion;
a first organic layer contacting the first lower electrode through the first pixel aperture;
a second organic layer contacting the second lower electrode through the second pixel aperture;
a first upper electrode provided on the first organic layer and contacting the lower portion;
a second upper electrode provided on the second organic layer and contacting the lower portion;
a sealing layer covering the first upper electrode and the second upper electrode and having a recessed portion located between the first lower electrode and the second lower electrode and provided directly above the partition; and
a lens provided above the sealing layer, formed in a protruding shape, and covering a part of a bottom surface of the recessed portion in a direction in which the first lower electrode and the second lower electrode are provided.

2. The display device of claim 1, further comprising:
a color filter layer provided above the sealing layer, wherein
the lens is located between the sealing layer and the color filter layer.

3. The display device of claim 2, wherein
the first organic layer and the second organic layer are configured to emit light in the same color, and
the color filter layer includes:
a first color filter provided above the first organic layer; and
a second color filter provided above the second organic layer and having a color different from that of the first color filter.

4. The display device of claim 3, wherein
the sealing layer includes:
a first sealing layer covering the first upper electrode, the second upper electrode, and the partition; and
a second sealing layer covering the first sealing layer.

5. The display device of claim 4, wherein
a thickness of the second sealing layer is smaller than that of the first sealing layer.

6. A display device, comprising:
a substrate;
a first lower electrode and a second lower electrode provided above the substrate and spaced apart from each other;
a rib layer provided on the first lower electrode and the second lower electrode and having a first pixel aperture overlapping the first lower electrode and a second pixel aperture overlapping the second lower electrode;
a partition comprising a lower portion provided on the rib layer and having conductivity and an upper portion provided on the lower portion and protruding relative to side surfaces of the lower portion;
a first organic layer contacting the first lower electrode through the first pixel aperture;
a second organic layer contacting the second lower electrode through the second pixel aperture;
a first upper electrode provided on the first organic layer and contacting the lower portion;
a second upper electrode provided on the second organic layer and contacting the lower portion;
a sealing layer covering the first upper electrode and the second upper electrode and having a recessed portion located between the first lower electrode and the second lower electrode and provided directly above the partition; and
a lens provided above the sealing layer, formed in a protruding shape, and entirely covering a bottom surface of the recessed portion in a direction in which the first lower electrode and the second lower electrode are provided.

7. The display device of claim 1, wherein
the first organic layer and the second organic layer are configured to emit light in mutually different colors.

8. The display device of claim 7, further comprising:
a color filter layer provided above the sealing layer and comprising:
a first color filter provided above the first organic layer and colored in the same color as a color emitted from the first organic layer; and
a second color filter provided above the second organic layer and colored in the same color as a color emitted from the second organic layer, wherein
the lens is located between the sealing layer and the color filter layer.

9. The display device of claim 7, wherein
the sealing layer includes:
a first sealing layer including a first portion covering the first upper electrode and a second portion covering the second upper electrode and spaced apart from the first portion directly above the partition; and
a second sealing layer covering the first sealing layer.

10. The display device of claim 9, wherein
a thickness of the second sealing layer is smaller than that of the first sealing layer.

11. The display device of claim 7, wherein
the sealing layer has a protrusion portion adjacent to the recessed portion.

12. The display device of claim 11, wherein
the lens covers the protrusion portion.

13. The display device of claim 1, wherein
the first pixel aperture is surrounded by the plurality of lenses in plan view.

14. The display device of claim 1, wherein
the first pixel aperture is surrounded by the lens in plan view.

15. The display device of claim 1, wherein
a refractive index of the lens is smaller than that of the sealing layer.

16. The display device of claim 1, wherein
the sealing layer is formed of an inorganic material.

17. The display device of claim 1, further comprising:
a resin layer covering the lens and having a refractive index smaller than that of the lens.

18. The display device of claim 17, wherein
a thickness of the resin layer is smaller than that of the sealing layer.

19. The display device of claim 17, further comprising:
a third sealing layer covering the resin layer; and
a color filter layer provided on the third sealing layer.

20. The display device of claim 19, wherein
a thickness of the third sealing layer is smaller than that of the sealing layer.
